(19) United States
(12) Patent Application Publication
(10) Pub. No.: US 2025/0358990 A1
(43) Pub. Date: Nov. 20, 2025

(54) Electromagnetic Interference Shielding and Thermal Management of Electronic Devices Using Thermomagnetic Composites

(71) Applicants: NORTHEASTERN UNIVERSITY, Boston, MA (US); VIRGINIA COMMONWEALTH UNIVERSITY, Richmond, VA (US)

(72) Inventors: Ogheneyunume FITCHOROVA, Acton, MA (US); Radhika BARUA, Glen Allen, VA (US); Vincent G. HARRIS, Sharon, MA (US); William SALTER, Montpelier, VA (US)

(21) Appl. No.: 18/869,525

(22) PCT Filed: Jun. 1, 2023
(86) PCT No.: PCT/US2023/024213

§ 371 Date: Nov. 26, 2024

Related U.S. Application Data
(60) Provisional application No. 63/347,978, filed on Jun. 1, 2022.

(51) Int. Cl. H05K 9/00; C09K 5/06; H01B 1/24; H01F 1/10; H01F 1/28; H01F 1/38; H01L 23/427; H01Q 1/02; H01Q 1/52; H01Q 17/00; H05K 7/20

(52) U.S. Cl. CPC H05K 9/0083; C09K 5/066; H01B 1/24; H01F 1/10; H01F 1/28; H01F 1/38; H01Q 1/02; H01Q 1/526; H01Q 17/002; H01Q 17/004; H01Q 17/007; H05K 7/20481; H01L 23/427

(57) ABSTRACT

Composite materials for simultaneous thermal management and electromagnetic interference screening of radiofrequency-based electronic systems are provided. The materials contain a phase change material and one or more electrically and thermally conductive filler particles. The materials provide a passive system for thermal management and EMI shielding that is lightweight, does not contain moving parts, and does not require an external power supply.

### CROSS-REFERENCE TO RELATED APPLICATIONS

This application claims the priority of U.S. Provisional Application No. 63/347,978 filed 1 Jun. 2022 and entitled “Electromagnetic Interference Shielding and Thermal Management of Electronic Devices Using Thermomagnetic Composites”, the whole of which is hereby incorporated by reference.

### BACKGROUND

Thermal radiation and interfering electromagnetic radiation are inevitable consequences of modern electronic devices. With the rapid advancement in electronics systems, there is a high demand in both the military and commercial sectors for components, systems and platforms that achieve size, weight, power, and cost reductions. The need for greater miniaturization and ongoing performance enhancements has contributed to a dramatic increase in heat generation (thermal radiation) within these systems. In RF magnetic-based components, which are mostly ferrite-based, temperature variations result in detrimental effects such as operating frequency drift and degradation of functional properties. Failure to effectively dissipate this heat away from key components leads to reliability concerns and reduced operational performance and system efficiencies.

Further, due to ever-increasing spectral congestion and higher operating frequencies, interference by electromagnetic radiation is becoming more difficult to eliminate. Signal interference can occur when multiple transmitting and receiving devices operating at similar frequency are close to each other. This interference which may be in the form of intermodulation, harmonics, or noise, leads to the degradation of device operation. EMI problems are further exacerbated by the move to smaller and lighter solutions. As a result, the choice of shielding is becoming more of a challenge for the designers of small consumer electronics.

Further, whether EM radiation is hazardous to human health is a controversial issue. While most researchers don't believe most EM radiation is hazardous to human health, some scientists have questioned the safety of its exposure and potential health effects. Many say there hasn't been enough research into understanding whether EM waves are safe. Nevertheless, it is prudent to minimize unwanted EMI with the appropriate shielding technology.

EMI shielding is conventionally made from metal enclosures or polymer composites with conducting fillers, or magnetic composites. Plastics offer the best prospects for lightweight packaging with EMI control. Though a polymer does not provide shielding, it can be modified using conductive plating, impregnation, paint, or spray. However, such solutions are expensive and do not provide thermal management suitable for small, modern devices.

There is an urgent need to develop efficient devices and materials that can concurrently control thermal and electromagnetic radiation for small electronics and electronic components.

### SUMMARY

The present technology provides graphene-based PCMs for thermal management and EMI screening of RF based electronic systems. The heterostructured composite material configuration is designed to enable compact passive thermal management solutions for magnetic components, and to provide a broader range of magnetic components to satisfy the current needs of size, weight, and power (SWaP) systems for both military and commercial industries. Three different topologies for the graphene-PCM composites are described, each with its own distinct advantages. One topology is a light-weight graphene aerogel/PCM composite that is flexible in shape and can thus be integrated with emerging RF devices such as wearable radio frequency coil garments for magnetic resonance imaging and ultra-broadband antennas incorporated into military armors). The present technology is a passive system that does not contain moving parts or require an external power supply. It is lightweight and less bulky than conventional solutions for thermal management and EMI shielding. The low thermal conductivity of the organic PCM when compared to metals is compensated by the exceptionally high thermal conductivity of 2D carbon-based nanostructures. The technology also provides EMI control and temperature management with the same part, which has been challenging to achieve. It can be used for passive thermal management and electromagnetic shielding in a wide variety of magnetic devices and RF components, including self-biased circulators, isolators, power cores for power electronics, and a wide variety of modern radar, communications, sensing, tracking, guided munitions, electronic warfare (EW), and other high-frequency systems.

The technology also can be summarized in the following listing of features.

1. A composite material for thermal regulation and electromagnetic interference shielding of an electronic device, the composite material comprising:
a phase change material capable of absorbing thermal radiation; and
a filler capable of reflecting or absorbing radio frequency electromagnetic radiation, the filler comprising an electrically and thermally conductive two-dimensional material, wherein the filler is mixed with the phase change material.

2. The composite material of feature 1, wherein the composite material comprises from about 5% to about 40% filler by volume.

3. The composite material of feature 1 or feature 2, wherein the phase change material comprises one or more n-alkanes, fatty acids, or esterified fatty acids having a chain length from about 16 to about 40 carbon atoms.

4. The composite material of any of the preceding features, wherein the phase change material has a melting temperature selected to provide an upper limit to an operating temperature of an electronic device comprising the composite material.

5. The composite material of feature 4, wherein the phase change material has a melting temperature from about 60° C. to about 130° C., such as about 85° C. or about 125° C.

6. The composite material of any of the preceding features, wherein the two-dimensional material comprises or consists of a carbon-based two-dimensional material selected from the group consisting of graphene, carbon nanotubes, and MXENEs.

7. The composite material of feature 6, wherein the two-dimensional material is graphene.

8. The composite material of any of the preceding features, wherein the composite material is configured as a matrix comprising the phase change material in which particles or flakes comprising the electrically and thermally conductive two-dimensional material are embedded.

9. The composite material of feature 8, wherein the electrically and thermally conductive two-dimensional material is configured as stacks of flakes embedded within the matrix comprising the phase change material.

10. The composite material of any of the preceding features, wherein the phase change material is configured as a porous aerogel in which particles or flakes comprising the electrically and thermally conductive two-dimensional material are embedded.

11. The composite material of any of features 1-7, wherein the material is configured as a plurality of core-shell particles, the core of the particles comprising the phase change material and the shell of the particles comprising the electrically and thermally conductive two-dimensional material.

12. The composite material of any of the preceding features, further comprising a additional filler, the additional filler comprising magnetic particles that provide tunable electromagnetic shielding in a selected frequency range.

13. The composite material of feature 12, wherein the magnetic particles comprise FeSi, SiC, CoNi, FeCo ZnO/carbonyl iron composite, a ferrite such as NiFe₂O₄, CoFe₂O₄, ZnFe₂O₄, NiFe₃O₄ or FeCo/C, of Y₂Fe₁₇.

14. The composite material of any of the preceding features, wherein the composite material is configured as a coating for an electronic device or a component thereof.

15. The composite material of feature 14, wherein the electronic device or a component thereof is a printed circuit board or a microelectronic or nanoelectronic chip.

16. An electronic device comprising the composite material of any of the preceding features.

17. The electronic device of feature 16, wherein the device is selected from the group consisting of a power core, an isolator, a phase shifter, a filter, and a self-biased circulator.

18. The electronic device of feature 16 which is a self-biased circulator, wherein the self-biased circulator is planar and/or shock-resistant.

19. The electronic device of any of features 16-18 comprising a temperature management substrate to accommodate the coating.

20. The electronic device of feature 19, wherein the thermal management substrate is a microwave ferrite substrate, a heterostructure, or a plastic shield.

21. The electronic device of feature 20 which is a microwave ferrite substrate that comprises barium hexaferrite.

22. The electronic device of any of features 16-21, wherein the device can operate in an environment having a temperature of up to at least 85° C., or up to at least 125° C. as a result of possessing said composite material.

23. A method of fabricating a composite material capable of thermal regulation and electromagnetic interference shielding of an electronic device, the method comprising the steps of:
(a) heating a phase change material to above its melting temperature;
(b) mixing an electrically and thermally conductive filler with the melted phase change material; and
(c) cooling the mixture resulting from step (b) to below the melting temperature of the phase change material, whereby the filler remains homogenously distributed within a matrix of the phase change material.

24. The method of feature 23, wherein the phase change material comprises one or more n-alkanes, fatty acids, or esterified fatty acids having a chain length from about 16 to about 40 carbon atoms.

25. The method of feature 23 or 24, further comprising, in step (b), mixing an additional filler comprising magnetic particles with the melted phase change material.

26. The method of feature 25, further comprising, in step (b), applying a magnetic field so as to orient the magnetic particles within the melted phase change material and, in step (c), maintaining the magnetic field so as to maintain the orientation of the magnetic particles established in step (b).

27. The method of any of features 23-26, wherein the two-dimensional material is a carbon-based two-dimensional material selected from the group consisting of graphene, carbon nanotubes, and MXENEs.

28. A method of fabricating a composite material capable of thermal regulation and electromagnetic interference shielding of an electronic device, the method comprising the steps of:
(a) providing a mixture comprising a phase change material dissolved in a solvent and an electrically and thermally conductive filler; and
(b) heating the mixture to above a boiling temperature of the solvent, whereby the mixture forms an aerogel, the aerogel comprising a scaffold comprising the filler and phase change material disposed in spaces within the scaffold.

29. The method of feature 28, further comprising applying vacuum during or after step (b).

30. The method of feature 28 or feature 29, further comprising, in step (a), providing an additional filler comprising magnetic particles and, in step (b),

31. The method of any of features 28-30, wherein the phase change material comprises one or more n-alkanes, fatty acids, or esterified fatty acids having a chain length from about 16 to about 40 carbon atoms.

32. The method of any of features 28-31, wherein in step (a) the mixture further comprises an additional filler comprising magnetic particles, and wherein the aerogel resulting from step (b) further comprises the additional filler.

33. The method of feature 32, further comprising, in step (b), applying a magnetic field so as to orient the magnetic particles.

34. The method of any of features 28-33, wherein the two-dimensional material is a carbon-based two-dimensional material selected from the group consisting of graphene, carbon nanotubes, and MXENEs.

35. A method of fabricating a composite material capable of thermal regulation and electromagnetic interference shielding of an electronic device, the method comprising the steps of:
(a) providing an aqueous mixture comprising a monomeric precursor of a phase change material, a surfactant, an initiator for polymerization of the monomer, and an electrically and thermally conductive two-dimensional material; and
(b) initiating polymerization of the monomer, whereby the phase change material is synthesized and core-shell particles are formed, the core of the particles comprising the phase change material and the shell of the particles comprising the two-dimensional material.

36. The method of feature 35, wherein the phase change material comprises one or more n-alkanes, fatty acids, or esterified fatty acids having a chain length from about 16 to about 40 carbon atoms.

37. The method of feature 35 or feature 36, wherein in step (a) the mixture further comprises magnetic particles, and wherein the shell of the particles resulting from step (b) comprises the magnetic particles.

38. The method of feature 37, further comprising, in step (b), applying a magnetic field so as to orient the magnetic particles.

39. The method of any of features 35-38, wherein the two-dimensional material is a carbon-based two-dimensional material selected from the group consisting of graphene, carbon nanotubes, and MXENEs.

40. A method of providing thermal management and electromagnetic interference shielding for an electronic device or component thereof, the method comprising:
(a) providing the composite material of any of features 1-15 and said electronic device or component thereof;
(b) heating the composite material to above a melting temperature of the composite material, whereby the composite material melts;
(c) applying a coating of the melted composite material to a surface of the electronic device or component thereof; and
(d) allowing the composite material to cool and form a solid coating on the surface of the electronic device or component thereof.

41. The method of feature 40, wherein step (c) comprises spin coating, painting, spraying, or screen printing the melted composite material on said surface.

42. A method of absorbing thermal radiation and shielding radiofrequency electromagnetic radiation at an electronic device, the method comprising:
(a) operating the electronic device of any of features 16-22;
(b) passively absorbing thermal radiation from the device by the coating; and
(c) passively reflecting or absorbing radiofrequency electromagnetic radiation incident on the device with the coating.

### BRIEF DESCRIPTION OF THE DRAWINGS

FIGS. 1A-1C illustrate different embodiments of composite materials according to the present technology. FIG. 1A shows at left a composite containing electrically and thermally conductive filler particles 240 (2D carbon-based nanostructures are represented) embedded in an phase change material 230, such as an organic phase change material. The right side of FIG. 1A is a scanning electron micrograph of an actual composite material of the type depicted at the left; specifically, the material shown in the micrograph contains graphene flakes embedded in paraffin. FIG. 1B shows a schematic illustration of an aerogel or foam embodiment of the composite material, in which phase change material 230 is embedded within a scaffold containing electrically conductive material 240. FIG. 1C shows a core-shell particle embodiment in which the core of each particle contains phase change material 230 and the shell contains electrically conductive material 240.

FIGS. 2A-2B are schematic illustrations of two embodiments of a composite material-electronic device heterostructure 200 according to the present technology, each configured as coating 220 layered over a surface of electronic device or component 210. In the embodiment depicted in FIG. 2A, the coating includes a first filler material 240 embedded in phase change material 230. In the embodiment of FIG. 2B, additional filler 250 is also embedded within the phase change material.

FIGS. 3A-3C show examples of conventional heat management structures for electronic devices. According to the present technology, one or more surfaces of such structures can be coated with any composite material according to the technology described herein.

FIG. 4 is an exploded perspective view of an embodiment of self-biased circulator utilizing a composite according to the present technology for heat and EMI shielding of the ferrite core.

FIG. 5A shows differential scanning calorimetry results for a series of paraffin-graphene composites at different graphene concentrations. In FIG. 5B, results are shown for the heat stability of spin coated paraffin-graphene (30% graphene) composites as a function of temperature.

FIG. 6 is a schematic representation of the role of latent heat and melting temperature in providing a range of temperature control for a device containing the composite material of the present technology.

FIG. 7 shows a comparison of magnetothermal behavior of a hexaferrite substrate with and without coating with paraffin.

FIG. 8 shows EMI shielding properties of different forms and concentrations of FeSiP-based fillers suspended in a paraffin matrix.

### DETAILED DESCRIPTION

The present technology provides a composite material that offers a simple and cost-effective passive solution to simultaneous EMI shielding and thermal management for higher frequency electronic devices and components. The composite material can be used as a lightweight passive system (requiring no external power source), that does not contain moving parts. Accordingly, the present technology offers a wider range of applications than conventional approaches for advanced for electronic systems necessitating the SWaP paradigm (i.e., reduction in size, weight, and power), particularly in newly developed two-dimensional passive radio frequency components where conventional strategy is based on the deployment of separate thermal interface materials, and electromagnetic interference (EMI) shielding materials that do not conform to the SWaP+C (size, weight, power, and cost) demands of emerging 5G and 6G technologies.

Thermal and electromagnetic (EM) radiation have an intrinsic connection, as absorption of EM waves by any material results in heating. The conventional strategy for handling thermal management and EM radiation complications is based on the deployment of separate materials: thermal interface materials that can dissipate the heat, and EMI shielding materials that can protect the device and its components from EM waves in the environment. However, this strategy does not conform to the SWaP+C demands of emerging 5G and 6G technologies. In contrast, the present technology avoids the need for separate technical solutions to heat and EMI through the use of a single multiphase coating that can absorb microwave radiation for effective shielding, while limiting the temperature rise by undergoing a latent phase change. The coating can be applied, for example, to a microwave ferrite substrate that forms the basis of a large number of magnetic devices operating in the high frequency range, devices such as power cores, isolators, phase shifters, filters, and the like.

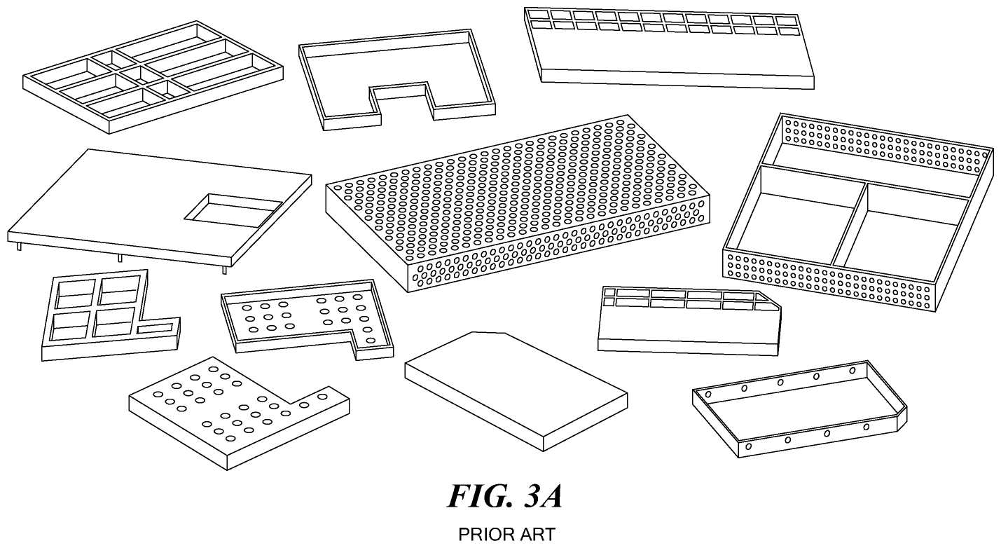

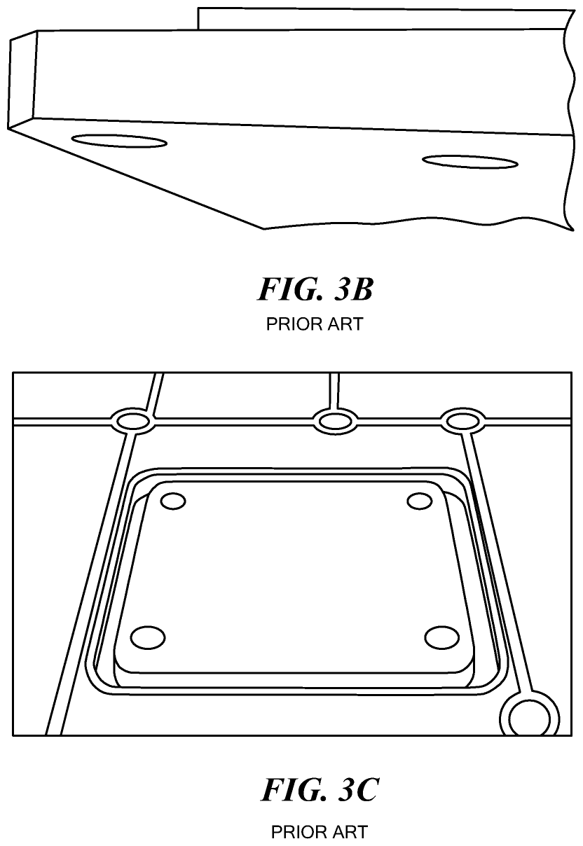

A board-level shield (BLS) with holes is generally used for thermal management and EMI shielding in electronics. A typical BLS is a five-sided, metal box mounted directly on the printed circuit board (PCB). Examples are shown in FIG. 3A. The SE of a BLS is highly dependent on the design of the PCB mounting area as the number and spacing of vias and traces affect the shielding. As frequency increases, the ventilation vias need to be smaller due to the shorter wavelength. However, with reduction in component size, more heat is generated and larger vias are needed for thermal management. As such, it is quite challenging to use the BLS alone for both thermal and EMI shielding management in higher frequency components/electronics, making device miniaturization difficult. Other conventional solutions shown in FIGS. 3B and 3C require solid metal shields above or below a PCB or component and suffer from similar deficiencies that are incompatible with miniaturization.

The 2D carbon-based nanomaterial-enhanced and magnetically-enhanced PCM/EMI shielding composites described here are more effective than conventional solutions for applications such as RF power amplifiers and phased array antenna modules, where size, weight, power and cost (SWaP+C) are high priorities. While the metal layers used for thermal management in magnetic flux shunts and printed circuit boards have a thickness in the millimeter range, a 2D nanomaterial foam suffused with PCM as described herein is lightweight and less bulky. Though the thermal conductivity of organic PCMs such as paraffin wax is very low (˜0.25 Wm-1K-1) when compared to metals (˜400-600 Wm-1K-1), this is compensated by the exceptionally high thermal conductivity of graphene (2000 Wm-1K-1) or other carbon-based 2D materials. Besides, it must be noted that the ability of organic PCMs such as paraffin to remove heat lies in its specific heat capacity of 2.14-2.9 J g-1 K-1 and high heat of fusion of 200-220 J g-1. Organic PCMs serve as excellent heat storage materials, and if needed the device design can be modified to harvest the waste thermal heat for other auxiliary power applications in the RF device.

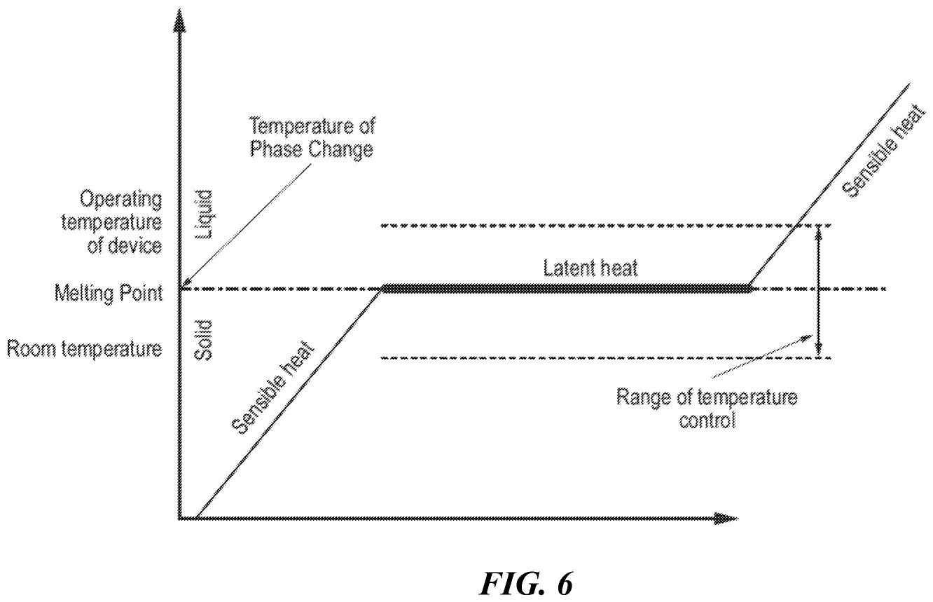

The present technology utilizes a single composite material that includes both thermal management provided by a phase change material and EMI shielding provided by one or more filler materials that are electrically conductive, and preferably also thermally conductive. Preferred filler materials are carbon-based two-dimensional materials which are both highly electrically conductive and thermally conductive. Preferred phase change materials are long chain n-alkanes, fatty acids, and esterified fatty acids; particularly preferred are those having a chain length from about 16 to about 40 carbon atoms, or from about 20 carbon atoms to about 38 carbon atoms, or from about 26 carbon atoms to about 36 carbon atoms. Phase change materials for use in the present technology have a high latent heat of fusion (i.e., the amount of heat absorbed when melting the material) and a high heat capacity (amount of heat required to raise the temperature of the material without a phase change). The melting temperature of the phase change material can be selected in order to provide a desired range of operating temperature for an associated electronic device. Preferably, the operating temperature is near the melting temperature of the phase change material or below the melting temperature. In general, using shorter chain length lowers the melting temperature, and longer chain length raises the melting temperature. See FIG. 6. A preferred combination is the use of paraffin as the phase change material and graphene flakes as the EMI shielding filler material.

Organic phase change materials can be used for cooling and energy storage applications in Li-ion batteries, automotive systems, and photovoltaic cells. Due to their intriguing, layered structure and high electrical conductivity, two-dimensional carbon-based materials (transition metal carbides (MXenes), graphene) are preferred for high-performance EMI shielding applications. Magnetic nanoparticles such as FeSiP, La(Fe,Si) and doped hexaferrites are also useful as filler materials to provide EMI shielding, as these materials conserve their magnetic permeability value at high frequency ranges. Combining PCM with layered carbides or magnetic nanoparticles results in a unique multifunctional composite that allows the exchange of thermal, electromagnetic, and magnetic energies effortlessly. This enables a wider range of applications than traditional approaches, thus addressing the needs of advanced RF electronic systems that require the SWaP paradigm. It also satisfies the long felt need to accomplish EMI control and thermal management with the same components.

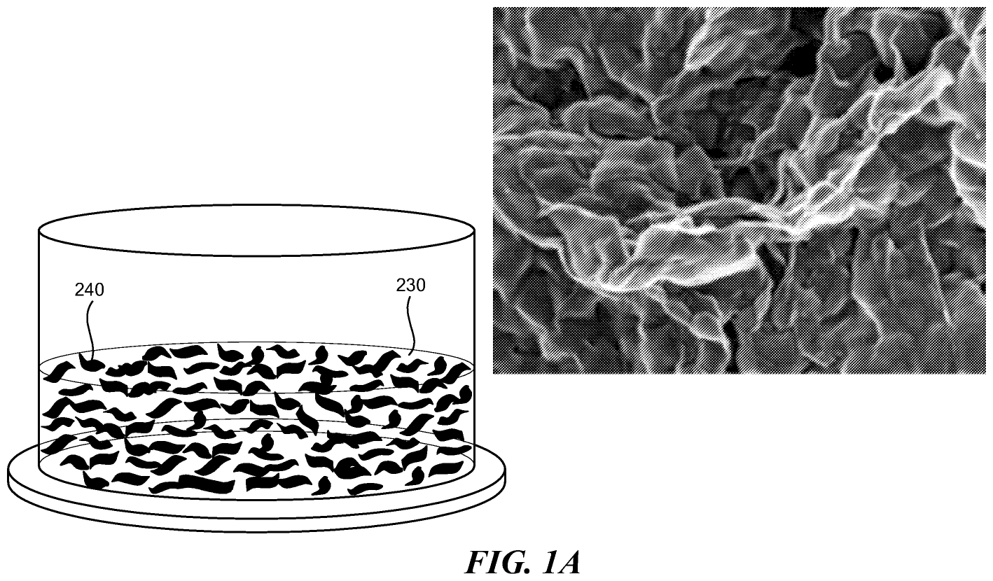

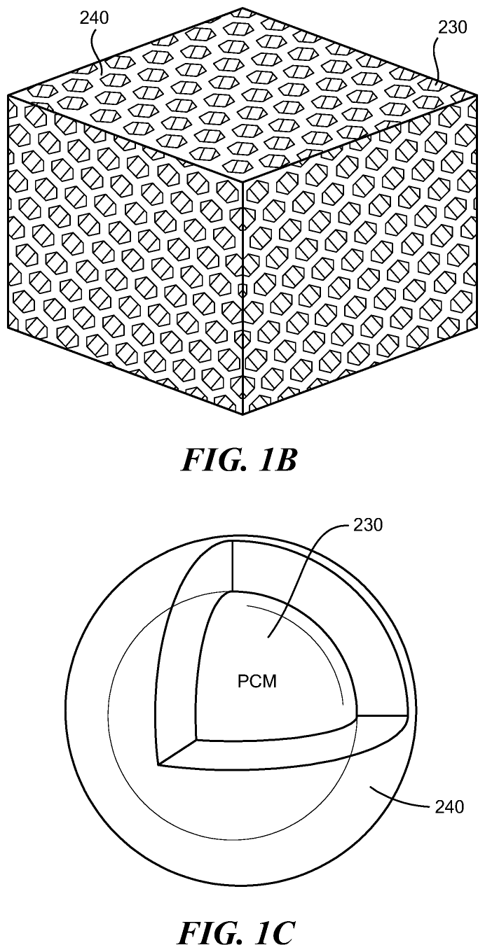

The present composite material can have one of three different topologies, which are depicted in FIGS. 1A-1C. The material depicted in FIG. 1A is a simple composite containing a matrix of a PCM in which are embedded filler particles or flakes, of any suitable size (including nanometer range, micrometer range, and larger), geometry (round, flat, irregular, or other shapes), and aspect ratio (at least 1 to 1000). Flakes or particles having a large aspect ratio can be either stacked or randomly arranged within the PCM matrix. The amount or concentration of filler particles or flakes can be as high as needed to provide desired EMI shielding and thermal conductivity. For example, the filler concentration can be up to 10, 15, 20, 25, 30, 35, 40, 45, 50, 55, or 60 vol % with 100% being the total volume of the composition. FIG. 1B shows an aerogel or foam configuration, containing a scaffold or skeleton structure containing or consisting of a material providing EMI shielding, and optionally high thermal conductivity, while the PCM is localized within pores of the gel or foam. A third structure is shown in FIG. 1C, which is a material containing or consisting of core-shall particles. The shell contains or consists of the EMI shielding material, and the core contains or consists of the PCM. Size of the core-shell particles can be in any desired range (nanometer range, micrometer range, or larger). The particles can be conveniently applied to fill spaces or cavities in a device or component or embedded in a matrix of another material to hold them in place.

Each of the different materials described above has its own distinct advantages. The simple composite is low cost and easy to prepare. The light-weight aerogel structures are flexible in shape and can thus be integrated with emerging RF devices, such as flexible and wearable radio frequency coil garments for magnetic resonance imaging and ultra-broadband antennas incorporated into military armors. The core-shell particles have higher thermal stability compared to a coating of homogeneous composite material.

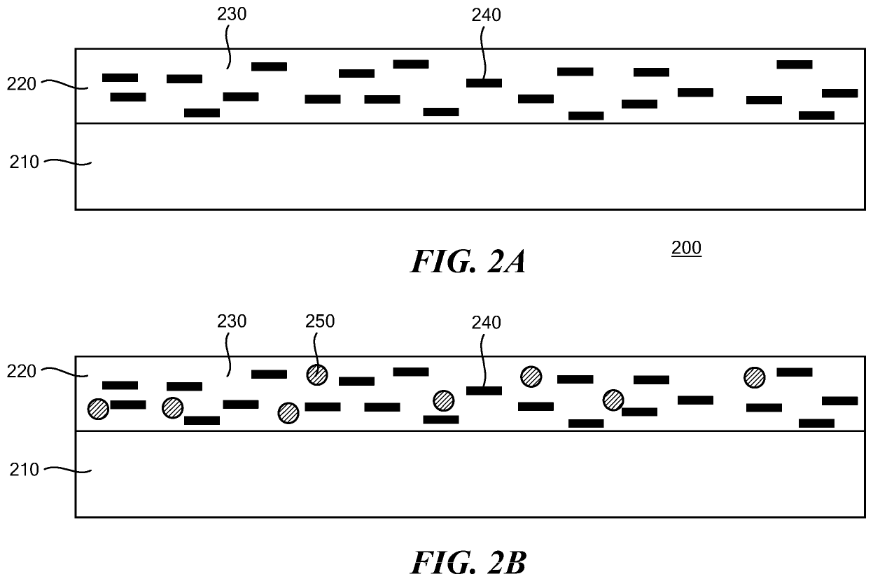

Two example configurations of device-composite heterostructures are shown in FIGS. 2A-2B. In the heterostructure of FIG. 2A, the composite material is applied as a coating to a surface of a device or component, and the composite contains one type of filler, which is preferably a carbon-based two-dimensional material. The heterostructure of FIG. 2B is similar, but the composite material coating also contains additional filler particles which are magnetic. These two types of heterostructures are designed to enable compact passive simultaneous EMI shielding and thermal management solutions to magnetic components, providing a novel system for a broader range of magnetic components to satisfy the current needs of SWaP systems for both military and commercial industries. It also has the added benefit that it satisfies the desired need to accomplish EMI control and thermal management with the same material.

### EXAMPLES

### Example 1. Synthesis of Composite Materials

### Method 1

An embodiment of the composite material configuration shown in FIG. 1A was prepared, containing paraffin as PCM and graphene flakes as filler. Paraffin was melted in a beaker employing a conventional hot plate. Graphene flakes were added to 20 vol %, and the mixture was stirred and sonicated for a few hours. The mixture was then cooled to solidification in a freezer to avoid gravitational settling of the graphene. This synthesis is scalable. The shape stability and thermal conductivity of the PCM-graphene composite depends upon the graphene loading.

### Method 2

An embodiment of the composite material configuration shown in FIG. 1B was prepared by preparing an aerogel of graphene which was infused with melted paraffin. The open-celled foam was made by heating single-layered sheets of graphene and paraffin to above the melting temperature of the paraffin. The melted paraffin was dissolved in a solvent, such as xylene. Paraffin-containing vapor was absorbed by the 3-D graphene aerogel for a few hours to form a shape stabilized composite material. Optionally, vacuum was applied to promote the absorption process. Solvent was removed by evaporation or applied vacuum.

### Method 3

The core-shell structures shown in FIG. 1C can be formed via in-situ polymerization, wherein the PCM is synthesized using a polymer-forming reaction carried out in water containing a surfactant, the monomeric precursor of the polymer, and a water-soluble polymerization initiator. This polymerization method offers desirable characteristics such as ready heat dissipation, less reliance on volatile organic solvents, and low viscosities even at high molecular weight.

### Example 2. Coating a Device with the Composite Material

A solution was prepared by mixing flakes or core-shell particles of the composite material flakes or core-shell structures with a solvent, such as butanol, hexane, or p-xylene. The solution was stirred and heated to above the melting temperature of the composite (e.g., up to 80° C.). The melted composite-solvent mixture was then deposited onto a heated device surface (e.g., a ferrite substrate) using spin-coating.

For applying an aerogel configuration of the composite, the aerogel can be attached to the device surface using a thermally conductive glue.

### Example 3. Self-Biased Circulator

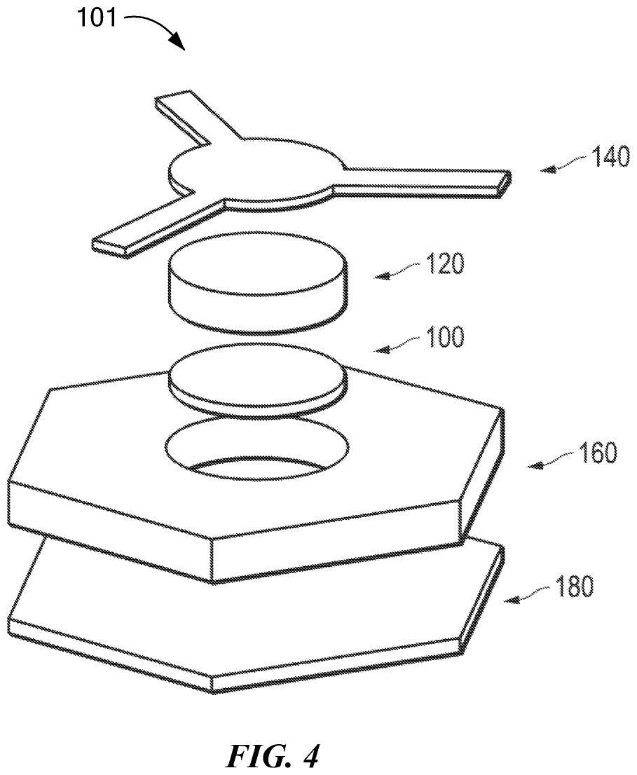

A self-biased circulator design for use with composites of the present technology is shown schematically in FIG. 4.

Circulators are a crucial three-port components in an RF front-end module which enable simultaneous transmit and receive (STAR) function via nonreciprocal operation. Conventional circulators are bulky due to the presence of heavy permanent magnets and are incompatible with monolithic microwave integrated circuit (MMIC) technologies. Planar self-biased circulators are an efficient alternative to the problem of full-duplex and antenna beam steering, because they are smaller, lighter, resistant to shock and vibration, and extremely economical. However, these two-dimensional RF components experience thermal stability issues that are unmet by conventional practices. In particular, forced convection cooling and heat sinks require bulky equipment, such as a fan and fins, which are far from suitable for system miniaturization and integration. The temperature rise reduces the electrical conductivity and, as a result, decreases the shielding efficiency of the material.

In the present design, the microwave ferrite substrate of the circulator can be coated with an ultrathin composite coating comprising of a phase change material modified by the inclusion of one or more thermally conductive fillers that demonstrate high microwave absorption efficiency. Discretely separate thermal interface materials (TIM) are avoided. Instead, with size and weight concerns in mind, a multiphase coating 100 is employed that can absorb microwave radiation for effective shielding, while simultaneously limiting the temperature rise by undergoing a latent phase change. This is achieved through the use of phase change materials as part of the coating. The circulator 101 includes microchip 140 that is affiliated with a conventional ferrite substrate 120. Dielectric layer 160 and grounding platform 180 are also provided. The coating 100 is applied to the microwave ferrite substrate 120.

### Example 4. Characteristics of Graphene-PCM Composite

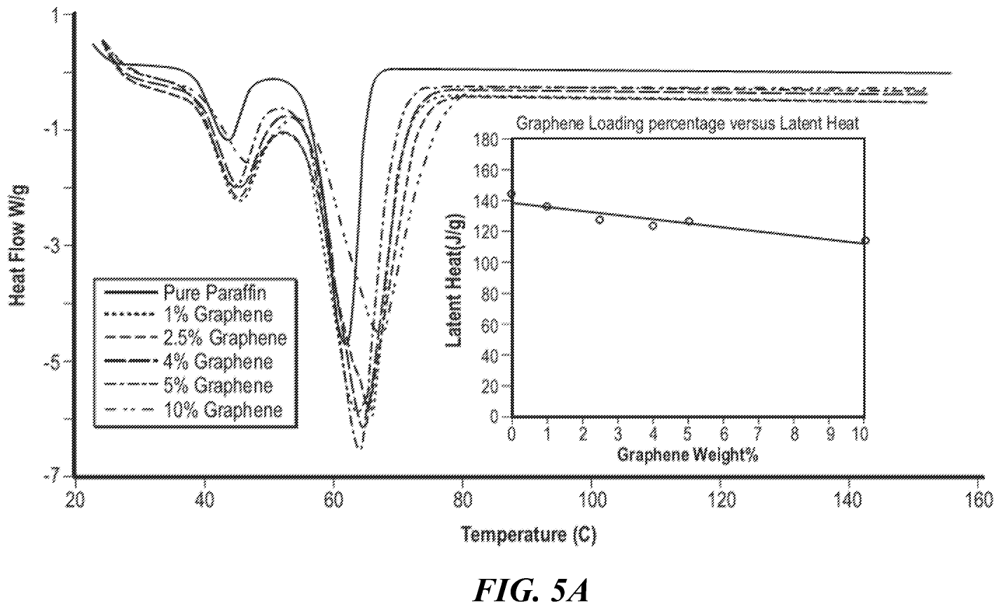

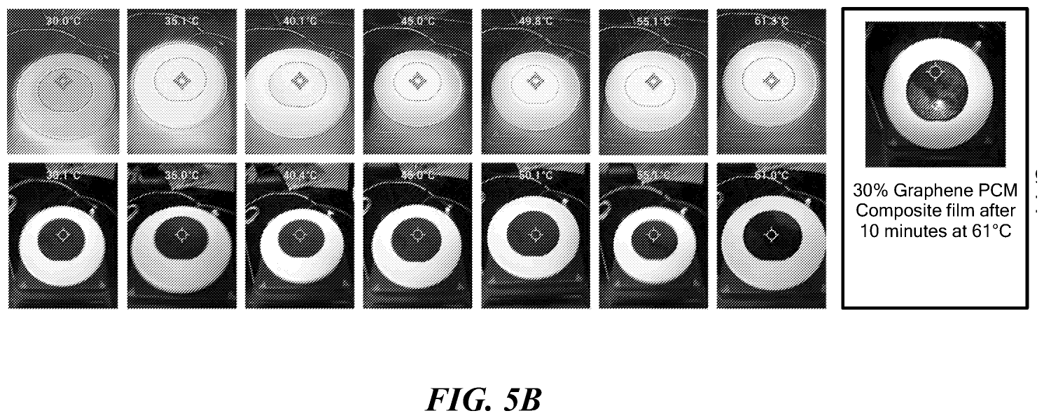

Hexatriacontane (C₃₆H₇₄) as PCM was melted in a beaker at a temperature above its melting point employing a conventional hot plate. Then graphene flakes were added to different concentrations as shown in FIG. 5A, and the mixtures were stirred and sonicated for a few hours. For coating, the mixtures were stirred and heated up to 80° C. and then deposited on heated ferrite or silicon substrates using glass pipettes which were kept at the same temperature as the paraffin solution. For spin coating, the silicon substrate is heated to 100° C. Spin coating was performed in two steps; first, the solution was spread at 500 rpm. Then, the spin speed was raised to 2000 rpm with an acceleration of 5000 rpm/s. An average thickness of 20 μm was obtained.

Calorimetry results indicated that the latent heat of the PCM drops very slightly upon addition of graphene. See FIG. 5A. As initial proof of concept of coating capability, a PCM-graphene flakes (30 vol %) was mixed with p-xylene (60% by volume) and coated on a silicon substrate. As seen in FIG. 5B, the coating was stable at up to 61° C.

### Example 5. Characteristics of Hexaferrite Films Coated with PCM Composite

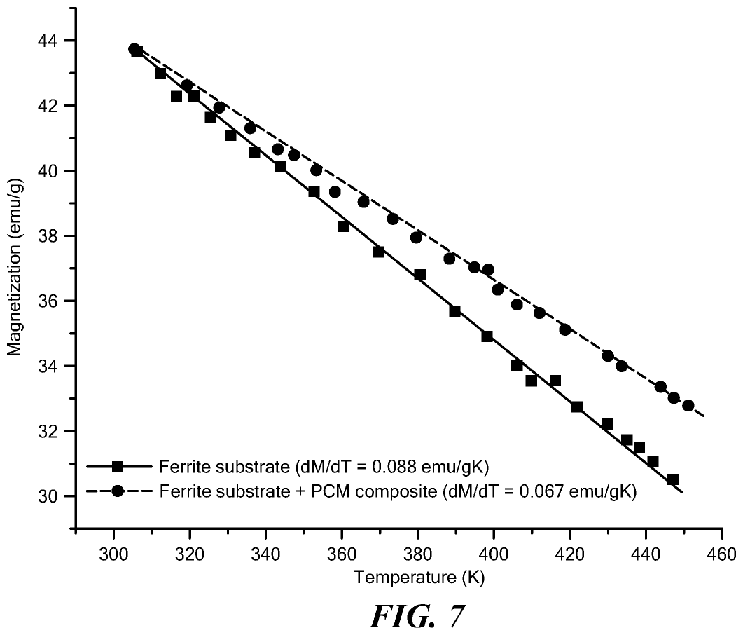

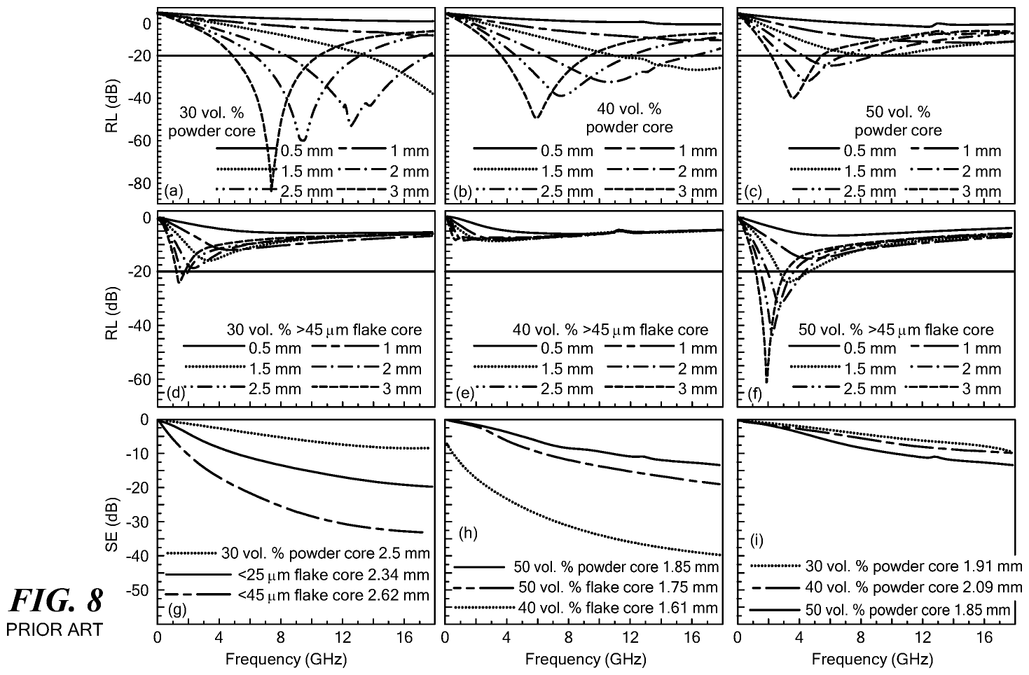

A barium hexaferrite film (6 mm×6 mm×1 mm in thickness) was coated on one side with a paraffin-graphene composite (˜0.5 mm in thickness). The magnetothermal behavior of the film was measured using magnetometry (see FIG. 7). It was found that the drop in magnetization as a function of temperature in the composite (dM/dT=0.067 emu/gK) was 23% lower, relative to that of the parent film (dM/dT=0.088 emu/gK).

### Example 6. Design Principles for Composites Containing PCM, Graphene, and Ferromagnetic Flakes

The goal of the design process is to select key adjustable parameters so as to optimize both EMI and thermal management performance in a composite containing a PCM matrix, ferromagnetic flakes, and/or carbon-based 2D conductive material such as graphene. Key parameters include the aspect ratio, particle distribution, and loading factor (particle concentration).

A modified EMT takes the magnetic suppression caused by the eddy currents into account where specifically a magneto-dielectric composite, made of mixing conductive particles homogenously with a polymer matrix, possesses an effective permeability m_{eff} given by (1) where mᵢ and mₘ are the permeability of the conductive particles and the polymer matrix respectively, and p is the volume fraction occupied by the particles.

The coefficient A modifies the intrinsic permeability of the conductive particles in the original equation. See eqn (2).

For spherical particles of radius R exposed to the magnetic field at frequency f, k is the propagation constant (3), and d is the skin depth (4).

For conductive particles, at a given frequency f, skin depth is dependent on the electrical conductivity s and the intrinsic permeability mᵢ as shown in the equation Due to the eddy-current effect, Eq. (1) becomes particle-size dependent. If the conductive inclusion consisting of various particle sizes and satisfying a particle-size distribution function f(R) in terms of particle radius R, the modified Bruggeman formula is written in integral form as (5). Where p is the total volume fraction occupied by the particles and p(R) is the volume-fraction function of particle size given by (6)

Based on the extended Bruggeman formula, the effective permeability of a multiphase system made of various particle sizes, either signal particles of multiple sizes or particle agglomerates due to clustering effect, can be predicted relying on the particle-size distribution.

$${μ}_{eff} = p \frac{A {μ}_{i} - {μ}_{eff}}{A {μ}_{i} + 2 {μ}_{eff}} + ( 1 - p ) \frac{{μ}_{m} - {μ}_{eff}}{{μ}_{m} + 2 {μ}_{eff}} = 0 \qquad ( 1 )$$

$$A = \frac{2 ( kR cos kR - sin kR )}{sin kR - kR cos kR - {( kR )}^{2} sin kR} \qquad ( 2 )$$

$$k = ( 1 + j ) \frac{1}{δ} \qquad ( 3 )$$

$$δ = \frac{1}{\sqrt{π f {μ}_{i} σ}} \qquad ( 4 )$$

$${\int }_{0}^{+ ∞} p ( R ) \frac{A ( R ) {μ}_{i} - {μ}_{eff}}{A ( R ) {μ}_{i} + 2 {μ}_{eff}} dR + ( 1 - p ) \frac{{μ}_{m} - {μ}_{eff}}{{μ}_{m} + 2 {μ}_{eff}} = 0 \qquad ( 5 )$$

$$p ( R ) = p \frac{f ( R ) {R}^{3}}{{\int }_{0}^{+ ∞} f ( R ) {R}^{3} dR} \qquad ( 6 )$$

### REFERENCES

1. Li, Q., Chen, Y., & Harris, V. G. (2019). Clustering effect on permeability spectra of magneto-dielectric composites with conductive magnetic inclusions. Journal of Applied Physics, 125(18), 185107.
2. Li, C., Wang, J., & Su, Y. (2021). A dual-role theory of the aspect ratio of the nanofillers for the thermal conductivity of graphene-polymer nanocomposites. International Journal of Engineering Science, 160, 103453.
3. Li, Q., Chen, Y., & Harris, V. G. (2018). Particle-size distribution modified effective medium theory and validation by magneto-dielectric Co—Ti substituted BaM ferrite composites. Journal of Magnetism and Magnetic Materials, 453, 44-47.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

1. A composite material for thermal regulation and electromagnetic interference shielding of an electronic device, the composite material comprising:
a phase change material capable of absorbing thermal radiation; and
a filler capable of reflecting or absorbing radio frequency electromagnetic radiation, the filler comprising an electrically and thermally conductive two-dimensional material, wherein the filler is mixed with the phase change material.

2. The composite material of claim 1, wherein the composite material comprises from about 5% to about 40% filler by volume.

3. The composite material of claim 1, wherein the phase change material comprises one or more n-alkanes, fatty acids, or esterified fatty acids having a chain length from about 16 to about 40 carbon atoms.

4. The composite material of claim 1, wherein the phase change material has a melting temperature selected to provide an upper limit to an operating temperature of an electronic device comprising the composite material.

5. The composite material of claim 4, wherein the phase change material has a melting temperature from about 60° C. to about 130° C., such as about 85° C. or about 125° C.

6. The composite material of claim 1, wherein the two-dimensional material comprises or consists of a carbon-based two-dimensional material selected from the group consisting of graphene, carbon nanotubes, and MXENEs.

7. The composite material of claim 6, wherein the two-dimensional material is graphene.

8. The composite material of claim 1, wherein the composite material is configured as a matrix comprising the phase change material in which particles or flakes comprising the electrically and thermally conductive two-dimensional material are embedded.

9. The composite material of claim 8, wherein the electrically and thermally conductive two-dimensional material is configured as stacks of flakes embedded within the matrix comprising the phase change material.

10. The composite material of claim 1, wherein the phase change material is configured as a porous aerogel in which particles or flakes comprising the electrically and thermally conductive two-dimensional material are embedded.

11. The composite material of claim 1, wherein the material is configured as a plurality of core-shell particles, the core of the particles comprising the phase change material and the shell of the particles comprising the electrically and thermally conductive two-dimensional material.

12. The composite material of claim 1, further comprising a additional filler, the additional filler comprising magnetic particles that provide tunable electromagnetic shielding in a selected frequency range.

13. The composite material of claim 12, wherein the magnetic particles comprise FeSi, SiC, CoNi, FeCo ZnO/carbonyl iron composite, a ferrite such as NiFe₂O₄, CoFe₂O₄, ZnFe₂O₄, NiFe₃O₄ or FeCo/C, of Y₂Fe₁₇.

14. The composite material of claim 1, wherein the composite material is configured as a coating for an electronic device or a component thereof.

15. The composite material of claim 14, wherein the electronic device or a component thereof is a printed circuit board or a microelectronic or nanoelectronic chip.

16. An electronic device comprising the composite material of claim 1.

17. The electronic device of claim 16, wherein the device is selected from the group consisting of a power core, an isolator, a phase shifter, a filter, and a self-biased circulator.

18. The electronic device of claim 16 which is a self-biased circulator, wherein the self-biased circulator is planar and/or shock-resistant.

19. The electronic device of claim 16 comprising a temperature management substrate to accommodate the coating.

20. The electronic device of claim 19, wherein the thermal management substrate is a microwave ferrite substrate, a heterostructure, or a plastic shield.

21. The electronic device of claim 20 which is a microwave ferrite substrate that comprises barium hexaferrite.

22. The electronic device of claim 16, wherein the device can operate in an environment having a temperature of up to at least 85° C., or up to at least 125° C. as a result of possessing said composite material.

23. A method of fabricating a composite material capable of thermal regulation and electromagnetic interference shielding of an electronic device, the method comprising the steps of:
(a) heating a phase change material to above its melting temperature;
(b) mixing an electrically and thermally conductive filler with the melted phase change material; and
(c) cooling the mixture resulting from step (b) to below the melting temperature of the phase change material, whereby the filler remains homogenously distributed within a matrix of the phase change material.

24. The method of claim 23, wherein the phase change material comprises one or more n-alkanes, fatty acids, or esterified fatty acids having a chain length from about 16 to about 40 carbon atoms.

25. The method of claim 23, further comprising, in step (b), mixing an additional filler comprising magnetic particles with the melted phase change material.

26. The method of claim 25, further comprising, in step (b), applying a magnetic field so as to orient the magnetic particles within the melted phase change material and, in step (c), maintaining the magnetic field so as to maintain the orientation of the magnetic particles established in step (b).

27. The method of claim 23, wherein the two-dimensional material is a carbon-based two-dimensional material selected from the group consisting of graphene, carbon nanotubes, and MXENEs.

28. A method of fabricating a composite material capable of thermal regulation and electromagnetic interference shielding of an electronic device, the method comprising the steps of:
(a) providing a mixture comprising a phase change material dissolved in a solvent and an electrically and thermally conductive filler; and
(b) heating the mixture to above a boiling temperature of the solvent, whereby the mixture forms an aerogel, the aerogel comprising a scaffold comprising the filler and phase change material disposed in spaces within the scaffold.

29. The method of claim 28, further comprising applying vacuum during or after step (b).

30. The method of claim 28, further comprising, in step (a), providing an additional filler comprising magnetic particles and, in step (b),

31. The method of claim 28, wherein the phase change material comprises one or more n-alkanes, fatty acids, or esterified fatty acids having a chain length from about 16 to about 40 carbon atoms.

32. The method of claim 28, wherein in step (a) the mixture further comprises an additional filler comprising magnetic particles, and wherein the aerogel resulting from step (b) further comprises the additional filler.

33. The method of claim 32, further comprising, in step (b), applying a magnetic field so as to orient the magnetic particles.

34. The method of claim 28, wherein the two-dimensional material is a carbon-based two-dimensional material selected from the group consisting of graphene, carbon nanotubes, and MXENEs.

35. A method of fabricating a composite material capable of thermal regulation and electromagnetic interference shielding of an electronic device, the method comprising the steps of:
(a) providing an aqueous mixture comprising a monomeric precursor of a phase change material, a surfactant, an initiator for polymerization of the monomer, and an electrically and thermally conductive two-dimensional material; and
(b) initiating polymerization of the monomer, whereby the phase change material is synthesized and core-shell particles are formed, the core of the particles comprising the phase change material and the shell of the particles comprising the two-dimensional material.

36. The method of claim 35, wherein the phase change material comprises one or more n-alkanes, fatty acids, or esterified fatty acids having a chain length from about 16 to about 40 carbon atoms.

37. The method of claim 35, wherein in step (a) the mixture further comprises magnetic particles, and wherein the shell of the particles resulting from step (b) comprises the magnetic particles.

38. The method of claim 37, further comprising, in step (b), applying a magnetic field so as to orient the magnetic particles.

39. The method of 35, wherein the two-dimensional material is a carbon-based two-dimensional material selected from the group consisting of graphene, carbon nanotubes, and MXENEs.

40. A method of providing thermal management and electromagnetic interference shielding for an electronic device or component thereof, the method comprising:
(a) providing the composite material of claim 1 and said electronic device or component thereof;
(b) heating the composite material to above a melting temperature of the composite material, whereby the composite material melts;
(c) applying a coating of the melted composite material to a surface of the electronic device or component thereof; and
(d) allowing the composite material to cool and form a solid coating on the surface of the electronic device or component thereof.

41. The method of claim 40, wherein step (c) comprises spin coating, painting, spraying, or screen printing the melted composite material on said surface.

42. A method of absorbing thermal radiation and shielding radiofrequency electromagnetic radiation at an electronic device, the method comprising:
(a) operating the electronic device of claim 16;
(b) passively absorbing thermal radiation from the device by the coating; and
(c) passively reflecting or absorbing radiofrequency electromagnetic radiation incident on the device with the coating.
